(19) United States
(12) Patent Application Publication
(10) Pub. No.: US 2026/0215300 A1
(43) Pub. Date: Jul. 23, 2026

(54) THERMAL RELEASE LAYER FOR CARRIER ASSISTED BOTTOM-UP PLATING

(71) Applicant: Intel Corporation, Santa Clara, CA (US)

(72) Inventors: Joseph PEOPLES, Gilbert, AZ (US); Aaditya Anand CANDADAI, Chandler, AZ (US); Whitney BRYKS, Tempe, AZ (US); Bainye Francoise ANGOUA, Phoenix, AZ (US); Dilan SENEVIRATNE, Phoenix, AZ (US)

(21) Appl. No.: 19/035,076

(22) Filed: Jan. 23, 2025

(51) Int. Cl. H01L 23/498; H01L 21/48; H01L 21/768; H01L 23/15

(52) U.S. Cl. CPC H10W 70/635; H10W 20/043; H10W 20/054; H10W 20/056; H10W 70/095; H10W 70/692

(57) ABSTRACT

Embodiments disclosed herein include an apparatus with a substrate that includes a glass layer. In an embodiment, an opening is provided through a thickness of the substrate, and the opening has a first end at a first surface of the substrate and a second end at a second surface of the substrate. In an embodiment, a layer is on a sidewall of the opening, and the layer is adjacent to the first end of the opening and extends along the sidewall of the opening a length that is less than ten percent of the thickness of the substrate. In an embodiment, the layer is electrically conductive. In an embodiment, a via is in the opening, and the via directly contacts the sidewall of the opening at a first location, and a gap is provided between the via and the sidewall of the opening at a second location.

### BACKGROUND

Glass cores for package substrates are an attractive option due to the increased stiffness and planarity that they provide compared to existing organic cores. However, the brittle nature of glass provides several challenges with respect to manufacturing. One issue that is present for glass cores is the high stress that is generated by vias that are formed through the glass core (i.e., through glass vias (TGVs)). With traditional plating, a seed layer is provided along the sidewalls of the via opening, and the via is plated out from the sidewalls. This provides a strong mechanical coupling between the vias and the glass core. During thermal cycling, the via expands more than the glass core, and this generates a high stress in the glass core. The high stress may result in cracking or other defects that significantly impact the reliability of the glass core.

### BRIEF DESCRIPTION OF THE DRAWINGS

FIG. 1A is a cross-sectional illustration of a glass core with a via that is plated with a bottom-up process, in accordance with an embodiment.

FIG. 1B is a cross-sectional illustration of a glass core with a via that is plated with a bottom-up process that includes a seed layer remnant at a bottom of the via, in accordance with an embodiment.

FIGS. 2A-2I are cross-sectional illustrations depicting a process for forming vias through a glass core substrate with a bottom-up plating process that includes a releasable carrier for improved planarity during processing, in accordance with an embodiment.

FIGS. 3A-3E are cross-sectional illustrations depicting a process for forming vias through a pair of glass cores with a double sided bottom-up plating process, in accordance with an embodiment.

FIG. 4 is a flow diagram that depicts a process for forming vias with a bottom-up plating process that includes a releasable carrier for improved planarity during processing, in accordance with an embodiment.

FIG. 5 is a cross-sectional illustration of an electronic system that comprises a package substrate with a glass core and vias that are formed with a bottom-up plating process, in accordance with an embodiment.

FIG. 6 is a schematic of a computing device built in accordance with an embodiment.

### EMBODIMENTS OF THE PRESENT DISCLOSURE

Described herein are glass substrates with vias formed with a bottom-up plating process using a releasable carrier, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide stiffness and/or improved planarity compared to organic cores. However, the strong mechanical coupling between the through glass vias (TGVs) and the glass core results in significant stress being induced in the glass core during thermal cycling. As such, cracking or other damage to the glass core may occur. This negatively impacts the reliability of such glass cores. Further, the high aspect ratios of the TGVs make it difficult to form void-free TGVs in a cost-effective manner. For example, an atomic layer deposition process may be used. However, atomic layer deposition is a slow and expensive process, and such a process may not be compatible with high volume manufacturing environments.

Accordingly, embodiments disclosed herein include a bottom-up plating process in order to form the TGVs. In a bottom-up plating process, an electrically conductive layer is provided across a bottom of the via opening. The plating proceeds in a vertical direction up through the via opening. In such an embodiment, the interface between the TGV and the sidewall has a weaker mechanical coupling than traditional plating from a seed layer along the sidewall of the via opening. For example, the TGV may have a sidewall that contacts the sidewall of the via opening in some locations and is spaced away from sidewall of the via opening by a gap (e.g., an air gap) at other locations. The gaps may have a width between the sidewall of the via opening and the TGV that is in the submicron scale. As such, the electrical conductivity is not significantly impacted while also allowing for improved mechanical reliability of the glass core.

Despite the improved rigidity of the glass core, bottom-up plating may lead to warpage during plating in some instances. For example, in a panel level process the large area and non-symmetric process (i.e., the bottom-up plating direction is non-symmetric) may lead to warpage. In order to improve the warpage, some embodiments described herein may add a carrier to the glass core during processing. The carrier may be attached to the glass core with a releasable adhesive layer. For example, a thermal release layer, an ultraviolet (UV) release layer, a laser release layer, or the like may be used.

In yet another embodiment, the planarity may be further improved through the use of a double sided fabrication process. In a double sided fabrication process, a first core may be attached to a top surface of the carrier, and a second core may be attached to a bottom surface of the carrier. Providing two cores turns the plating process into a more symmetric process. The double sided fabrication process also allows for improved throughput.

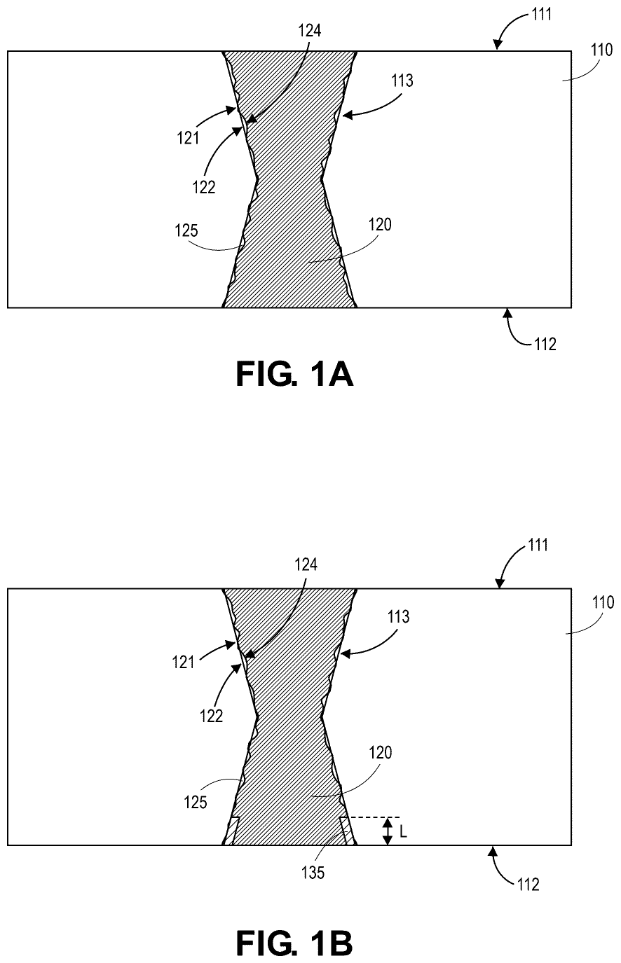

Referring now to FIG. 1A, a cross-sectional illustration of a glass core 110 with a TGV 120 that passes through a first surface 111 to a second surface 112 is shown, in accordance with an embodiment. In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 150 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

In an embodiment, the TGV 120 passes through an opening in the glass core 110 that is defined by sidewall 113. In the illustrated embodiment, the sidewall 113 may be sloped. For example, the sidewall 113 in FIG. 1A defines an hourglass shaped via opening. Though, in other embodiments, the sidewalls 113 may have any suitable profile, depending on the process used to form the opening through glass core 110.

In an embodiment, the TGV 120 is formed with a bottom-up plating process. The bottom-up plating process will be described in greater detail below. The bottom-up plating process may result in the formation of gaps 125 between a sidewall 124 of the TGV 120 and the sidewall 113 of the opening through the glass core 110. However, there may also be positions through the height of the TGV 120 where the sidewall 124 directly contacts the sidewall 113 of the opening through the glass core 110. For example, the sidewall 124 of the TGV 120 may contact the sidewall 113 of the opening through the glass core 110 at a first location 121, and a sidewall 124 is spaced away from the sidewall of the opening through the glass core 110 by a gap 125 at a second location 122. In an embodiment, the gap 125 may have a width that is approximately 1 micron or less, approximately 500 nm or less, approximately 100 nm or less, or approximately 50 nm or less. In contrast, a TGV 120 that is plated out from the sidewall 113 of the opening through the glass core 110 may not have a discernable gap 125 between the TGV 120 and the sidewall 113 since the TGV 120 would plate out from the sidewall 113.

Referring now to FIG. 1B, a cross-sectional illustration of a glass core 110 is shown, in accordance with an additional embodiment. The glass core 110 in FIG. 1B may be similar to the glass core 110 in FIG. 1A, with the exception of the bottom of the TGV 120. As shown, a layer 135 is provided on the sidewall 113 of the opening adjacent to a bottom end of the opening. The bottom end of the opening may be the opening that is closest to the plating surface (as will be described in greater detail below). In an embodiment, the layer 135 may extend along the sidewall 113 of the opening a length L into the thickness of the glass core 110. The length L may be less than 10% of the a thickness of the glass core 110, less than 2% of the thickness of the glass core 110, or less than 0.5% of the thickness of the glass core 110.

In an embodiment, the layer 135 may be a remnant of the seed layer that is provided below the glass core 110 during the bottom-up plating process. During the formation of the seed layer, a portion of the seed layer 135 may form along the sidewall 113 at the bottom end of the opening through the glass core 110. As such, the layer 135 may comprise a seed layer material, such as one or more of titanium, copper, ruthenium, or the like. Since the layer 135 is part of the seed layer, the TGV 120 may plate out from the layer 135, and the layer 135 may directly contact the TGV 120.

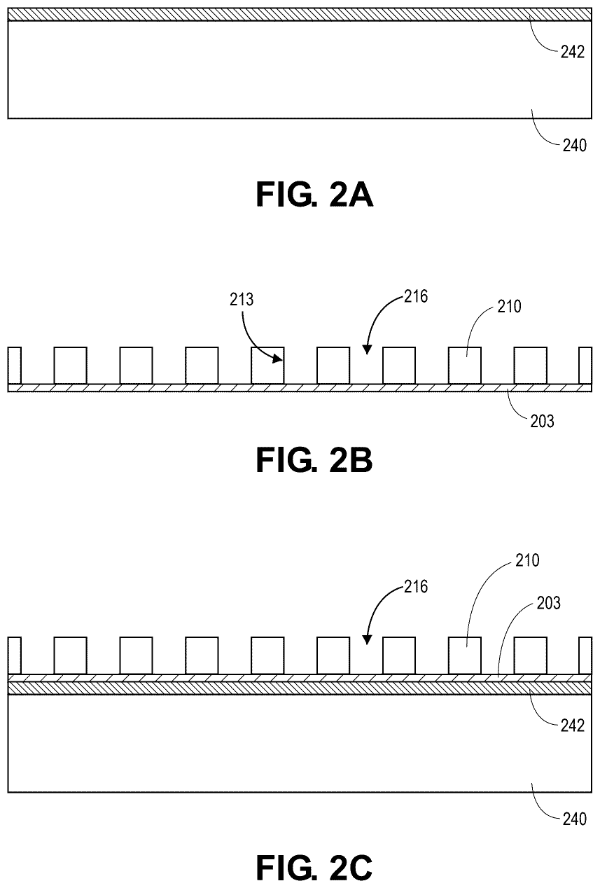

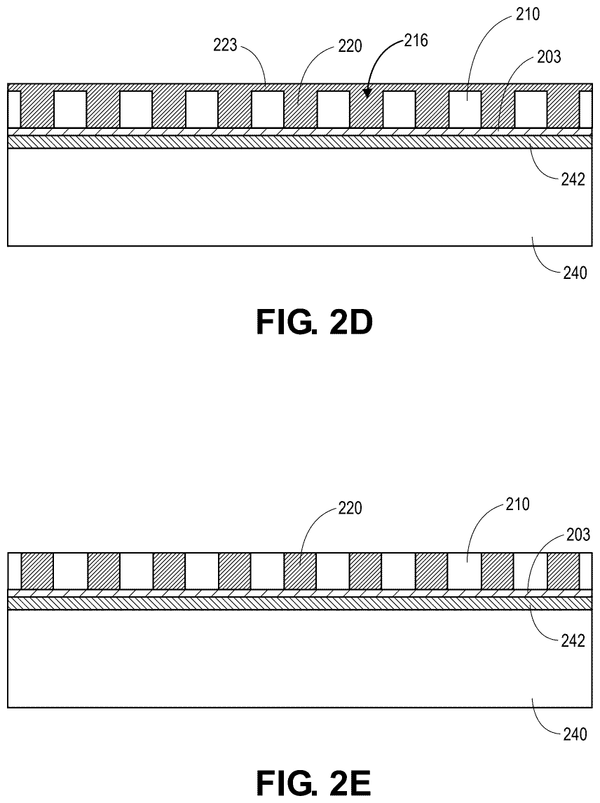

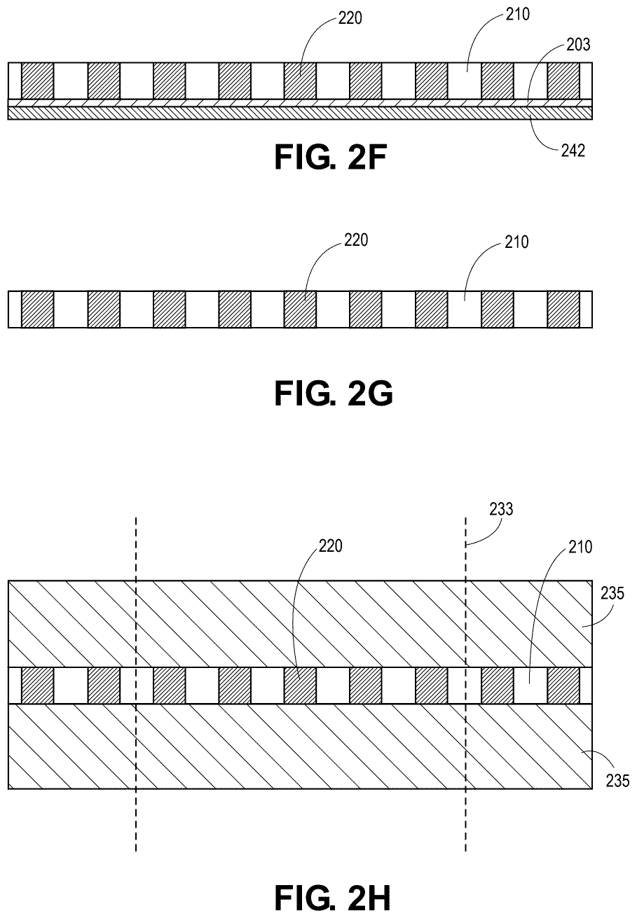

In the embodiments described above with respect to FIGS. 1A and 1B, a description of the resulting structure of the TGV 120 and the sidewall 124 of the TGV 120 with respect to the sidewall 113 of the opening through the glass core 110 is shown. An example of how such a process may be implemented in a manufacturing setting is shown with respect to FIGS. 2A-2I . Particularly, the profile and detail of the TGVs 120 in FIGS. 1A and 1B are omitted in order to direct focus to the processing and structures used to enable the bottom-up plating process. Though, it is to be appreciated that the structure, composition, and/or the like of the TGVs 220 in FIGS. 2A-2I may be similar to any of those described in greater detail herein.

Referring now to FIGS. 2A-2I , a series of cross-sectional illustrations depicting a process for forming a TGV 220 in a glass core with a bottom-up plating process with the use of a releasable carrier is shown, in accordance with an embodiment.

Referring now to FIG. 2A, a cross-sectional illustration of a carrier 240 is shown, in accordance with an embodiment. In an embodiment, the carrier 240 may comprise a rigid material that provides mechanical stability and resistance to warpage. In some embodiments, the carrier 240 may be a glass layer. The use of a glass layer may be beneficial since the coefficient of thermal expansion (CTE) of the carrier 240 may match the CTE of the glass core (not shown in FIG. 2A) that will be processed. Though, other materials may also be used for the carrier 240 in some embodiments (e.g., a metallic carrier 240, a ceramic carrier 240, a silicon carrier 240, or the like).

In an embodiment, a releasable adhesive layer 242 may be formed over a surface of the carrier 240. The releasable adhesive layer 242 may be a material that provides good adhesion strength with a conductive layer used for plating, and the releasable adhesive layer 242 may also be deactivated (i.e., to release the carrier 240) after the bottom-up plating process. For example, the releasable adhesive layer 242 may be deactivated by applying a particular stimulus to the releasable adhesive layer. For example, the releasable adhesive layer may be deactivated with a stimulus, such as a thermal stimulus (e.g., heat), a UV stimulus, a laser stimulus, or the like. The releasable adhesive layer 242 may be deposited on the carrier 240 with a slit coating process, a lamination process, or the like. In some embodiments, a baking and/or a drying process may be implemented on the releasable adhesive layer 242 after the releasable adhesive layer 242 has been added to the carrier 240.

In the case of a thermal stimulus, the thermal stimulus may trigger a decrease in a viscosity of the adhesive layer 242 past a specified temperature threshold. When the viscosity is decreased, a debonding process may occur by mechanically pushing overlying layers off of the carrier 240 while at high temperature (e.g., with a “thermal slide” release process). In some embodiments, the thermal stimulus may result in a thermal decomposition of the adhesive layer 242. When thermal decomposition occurs, an essentially zero-force debond process may be used, which can provide additional protection to the glass core since the glass core is subjected to fewer stresses during fabrication. Some suitable materials that undergo thermal decomposition that can be used for the adhesive layer 242 may include polyalkylcarbonates, cyclic poly(pthalaldehyde) (cPPA), or the like.

Referring now to FIG. 2B, a cross-sectional illustration of a glass core 210 is shown, in accordance with an embodiment. The glass core 210 may be similar to any of the glass cores described in greater detail herein. In a particular embodiment, the glass core 210 may be a panel level structure. Though, the glass core 210 may have any form factor. In an embodiment, via openings 216 may be provided through a thickness of the glass core 210. The via openings 216 may be formed with any suitable process. For example, a laser assisted etching process may be used to form the via openings 216 in some embodiments. In an embodiment, the via openings 216 may be a high aspect ratio via openings 216. For example, an aspect ratio (height:width) of the via opening 216 may be 5:1 or greater, 10:1 or greater, or 20:1 or greater. Though, embodiments may also be used with smaller aspect ratio via openings 216 as well.

In the illustrated embodiment, sidewalls 213 of the via opening 216 have a slope relative to a top surface and a bottom surface of the glass core 210. The via opening 216 may have sidewalls 213 that form an hourglass shape. Though, in other embodiments, the sidewalls 213 may have a single slope to form a via opening 216 with a single taper. In other embodiments, the sidewalls 213 may be substantially vertical (i.e., orthogonal to the top surface), the sidewalls 213 may be curved (e.g., non-planar), or have any other suitable profile.

In an embodiment, a seed layer 203 may be formed over the bottom surface of the glass core 210. The seed layer 203 may span across the via opening 216. In an embodiment, the seed layer 203 may include an electrically conductive material, such as a material comprising one or more of titanium, copper, ruthenium or the like. In an embodiment, the seed layer 203 may be applied to the glass core 210 with an electroless plating process, a lamination process, a slit coating process, or the like. The seed layer 203 may also be a thin foil, a film, or the like. As noted above with respect to FIG. 1B, a portion of the seed layer 203 may deposit on a lower end of sidewall 213 the via openings 216.

Referring now to FIG. 2C, a cross-sectional illustration of the glass core 210 after the glass core 210 is attached to the carrier 240 is shown, in accordance with an embodiment. In an embodiment, the glass core 210 may be bonded to the carrier 240 by the releasable adhesive layer 242. For example, a heating process may be used to improve the bonding between the seed layer 203 and the releasable adhesive layer 242.

Referring now to FIG. 2D. a cross-sectional illustration of the glass core 210 after the TGVs 220 are plated is shown, in accordance with an embodiment. In an embodiment, the plating of the TGVs 220 starts at the seed layer 203 and extends in a vertical direction away from the seed layer 203 in a bottom-up manner. In an embodiment, the bottom-up plating process may result in the formation of overburden 223 above the glass core 210. The plating may be any suitable electroplating process. Due to the bottom-up plating process, the sidewalls of the TGVs 220 may have a textured surface that interfaces with the sidewall of the via openings 216 similar to embodiments described above with respect to FIGS. 1A and 1B. For example, the sidewalls of the TGVs 220 may be non-linear with peaks and valleys. Further, the sidewalls of the TGVs 220 may directly contact the sidewalls of the via openings 216 at some locations, and the sidewalls of the TGVs 220 may be spaced away from the sidewalls of the via openings 216 by a gap at other locations.

In an embodiment, the TGVs 220 directly contacting the sidewalls of the via openings 216 may refer to there being no intermediary layer between the TGVs 220 and the sidewall of the via openings 216. For example, in existing plating processes, a seed layer or the like may be provided between the sidewalls of the via openings 216 and the sidewalls of the TGVs 220. In an embodiment, the gaps may have any suitable dimension. For example, a width of the gaps between the sidewalls of the via openings 216 and the sidewall of the TGVs 220 may be up to approximately 5 μm, up to approximately 1 μm, up to approximately 0.5 μm, or up to approximately 0.1 μm.

In an embodiment, the TGVs 220 substantially fill the via openings 216, with the exception of the presence of gaps at some locations along the height of the TGVs 220. In a particular embodiment, a cross-sectional area of the TGVs 220 along a plane (e.g., the plane illustrated in FIG. 2D) may be smaller than a cross-sectional area of a portion of the via opening 216 along the same plane. In an embodiment, the difference between the cross-sectional areas of the portion of the via opening 216 and the TGV 220 may be occupied by the cross-sectional area of all of the gaps. In an embodiment, the cross-sectional area of the TGV 220 along the plane may be approximately 95% or more of the cross-sectional area of the portion of the via opening 216, approximately 99% or more of the cross-sectional area of the via opening 216, approximately 99.5% or more of the cross-sectional area of the via opening 216, or approximately 99.9% or more of the cross-sectional area of the via opening 216.

In an embodiment, the TGV 220 may comprise a substantially uniform composition across a line from a first edge of the TGV 220 to a second edge of the TGV 220 that is parallel to the top surface or the bottom surface of the glass core 210. For example, the TGV 220 may have a substantially uniform composition comprising copper. This is different than many existing via architectures that include a seed layer along the sidewall of the via opening 216. In such an embodiment, the TGV 220 may have a different composition along the outer edge of the TGV 220 due to the seed layer. For example, concentrations of titanium or other seed layer materials may be present at the edge of the TGV. However, embodiments disclosed herein may comprise some amount of seed layer remnant along a bottom portion of the via opening 216, similar to the embodiment described with respect to FIG. 1B.

As noted above, the presence of the gaps allow for weaker mechanical coupling between the TGVs 220 and the glass core 210. Accordingly, stress related to CTE mismatch between the glass core 210 and the TGV 220 may be mitigated, and the mechanical robustness of the glass core 210 is improved.

Referring now to FIG. 2E, a cross-sectional illustration of the glass core 210 after the overburden 223 is removed is shown, in accordance with an embodiment. In an embodiment, the overburden 223 may be removed with a polishing process, a planarization process, an etching process, or the like. In a particular embodiment, a chemical mechanical polishing (CMP) process is used to remove the overburden 223.

Referring now to FIG. 2F, a cross-sectional illustration of the glass core 210 after the carrier 240 is removed is shown, in accordance with an embodiment. In an embodiment, the carrier 240 may be removed by applying a stimulus that is configured to deactivate the adhesive properties of the releasable adhesive layer 242. For example, the stimulus may include a thermal stimulus, a UV stimulus, a laser stimulus, or the like. While the releasable adhesive layer 242 is shown in FIG. 2F, it is to be appreciated that under some release stimuli, the adhesive layer 242 may be removed (e.g., as would be the case in a thermally decomposed adhesive layer 242). When the releasable adhesive layer 242 is decomposed or otherwise removed, some surface residue from the adhesive layer 242 may still be present in some embodiments.

Referring now to FIG. 2G, a cross-sectional illustration of the glass core 210 after the releasable adhesive layer 242 and the conductive layer 203 are removed is shown, in accordance with an embodiment. In an embodiment, the releasable adhesive layer 242 and the conductive layer 203 may be removed with an etching process, a polishing process, and/or the like. Due to the presence of the conductive layer 203, the bottom surface of the TGV 220 may be substantially flat and coplanar with the bottom surface of the glass core 210. In some embodiments, the top surface of the TGV 220 may be polished or planarized so that the top surface is substantially flat and coplanar with the top surface of the glass core 210.

Referring now to FIG. 2H, a cross-sectional illustration of the glass core 210 after buildup layers 235 are formed over and under the glass core 210 is shown, in accordance with an embodiment. In an embodiment, the buildup layers 235 may comprise laminated layers of organic buildup film. Electrical routing (not shown) may be provided within the routing buildup layers 235. As shown in FIG. 2H, dashed lines 233 may be provided through the buildup layers 235 and the glass core 210. The dashed lines 233 may be the location where the glass core 210 panel is singulated into individual units.

Referring now to FIG. 2I, a cross-sectional illustration of a package substrate 200 that has been singulated from the panel is shown, in accordance with an embodiment. As shown, one or more dies 239 may be electrically coupled to the buildup layers 235 by interconnects 238. The interconnects 238 may comprise any suitable first level interconnect (FLI), such as a solder ball, a copper bump, a hybrid bonding interface, or the like. The one or more dies 239 may include any type of die, such as a processor, a graphics processor, a memory die, or the like. In an embodiment, second level interconnects (SLIs) 237 are coupled to a bottom of the buildup layers 235. The SLIs 237 may be any type of SLI, such as a solder ball, a socket, or the like.

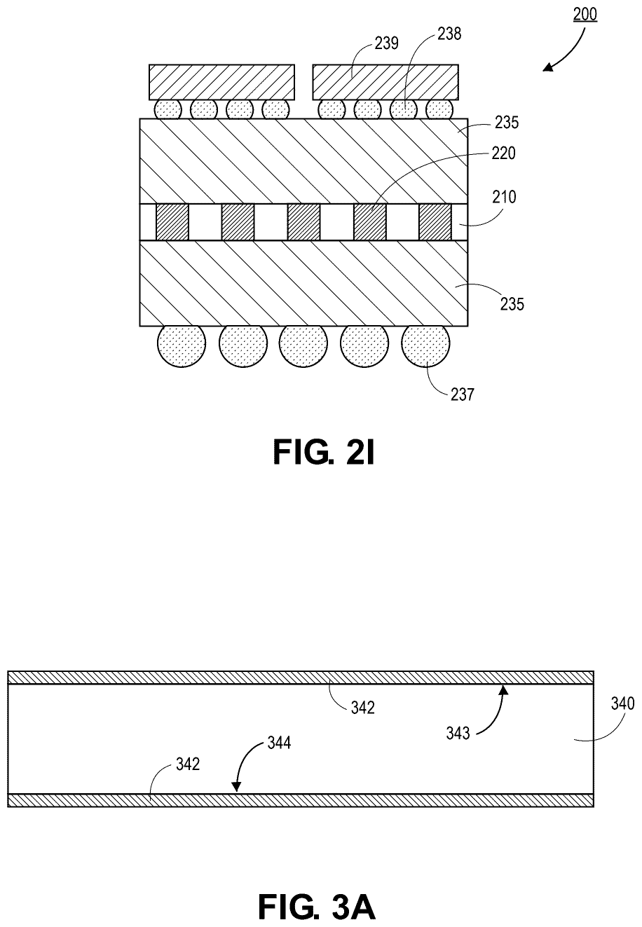

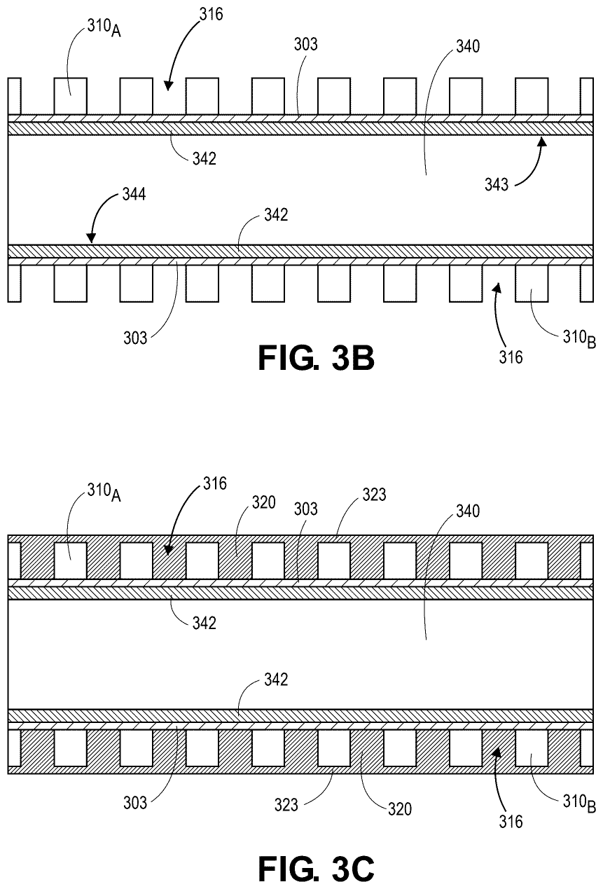

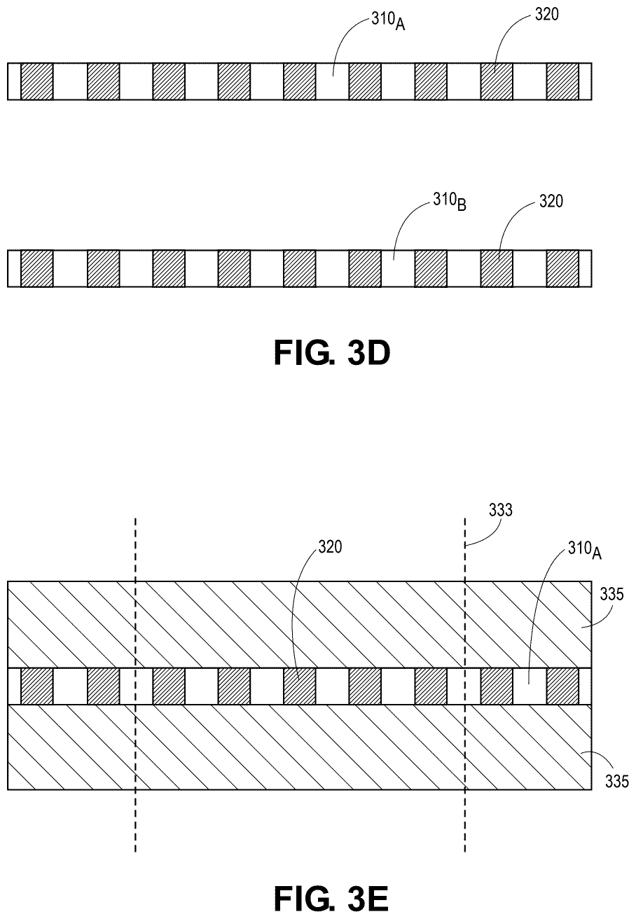

In the embodiment shown in FIGS. 2A-2I , a single glass core 210 is coupled to the carrier 240 in order to provide the bottom-up TGV plating. Though, in other embodiments, a pair of glass cores 210 may be mounted to the carrier 240 (i.e., one on each side) in order to provide double sided bottom-up TGV plating, in accordance with an embodiment. Such a double sided process is described with respect to FIGS. 3A-3E.

Referring now to FIG. 3A, a cross-sectional illustration of a carrier 340 is shown, in accordance with an embodiment. In an embodiment, the carrier 340 may be similar to the carrier 240 described above. However, in an embodiment, releasable adhesive layers 342 may be provided on a top surface 343 of the carrier 340 and a bottom surface 344 of the carrier 340. The releasable adhesive layers 342 may be similar to the releasable adhesive layer 242 described in greater detail herein.

Referring now to FIG. 3B, a cross-sectional illustration of the carrier 340 after a first glass core 310_{A} is attached to the top surface 343 of the carrier 340 and a second glass core 310_{B} is attached to the bottom surface 344 of the carrier 340. In an embodiment, the conductive seed layers 303 may be provided between the first glass core 310_{A} and the releasable adhesive layer 342 on the top surface 343 of the carrier 340 and between the second glass core 310_{B} and the releasable layer 342 on the bottom surface 344 of the carrier 340. The seed layers 303 may span across via openings 316 through the glass cores 310_{A} and 310_{B}. In an embodiment, the glass cores 310_{A} and 310_{B} may be similar to any of the glass cores described in greater detail herein.

Referring now to FIG. 3C, a cross-sectional illustration of the carrier 340 after TGVs 320 are plated up from the seed layers 303 in the via openings 316 with a bottom-up plating process is shown, in accordance with an embodiment. Since the plating occurs both above and below the carrier 340, the plating is more symmetric. This may result in even better planarity since stresses are balanced on both sides of the carrier 340. In an embodiment, the plating may result in TGVs 320 that have textured sidewalls that contact some portions of the sidewalls of the via openings 316 and are spaced away from other portions of the sidewalls of the via openings 316 by gaps. In an embodiment, overburden 323 may plate up over the glass cores 310_{A} and 310_{B}.

Referring now to FIG. 3D, a cross-sectional illustration of the carrier 340 after the overburden 323 has been polished and the glass cores 310_{A} and 310_{B} are removed from the carrier 340 is shown, in accordance with an embodiment. In an embodiment, the overburden 323 may be removed with a polishing process (e.g., CMP or the like). After the overburden 323 is removed, a stimulus to deactivate the releasable adhesive layer 342 is applied to the carrier 340. For example, a thermal stimulus, a UV stimulus, a laser stimulus, or the like may be used. After the glass cores 310_{A} and 310_{B} are removed, the seed layers 303 may be removed with an etching process, or the like.

Referring now to FIG. 3E, a cross-sectional illustration of the first glass core 310_{A} after buildup layers 335 are formed over and under the glass core 310_{A} is shown, in accordance with an embodiment. In an embodiment, the buildup layers 335 may comprise laminated layers of buildup film with electrical routing (not shown) integrated into the buildup layers 335. In an embodiment, dashed lines 333 may indicate where the structure is to be singulated to form a plurality of individual units from a panel, similar to the embodiments shown in FIGS. 2H and 2I.

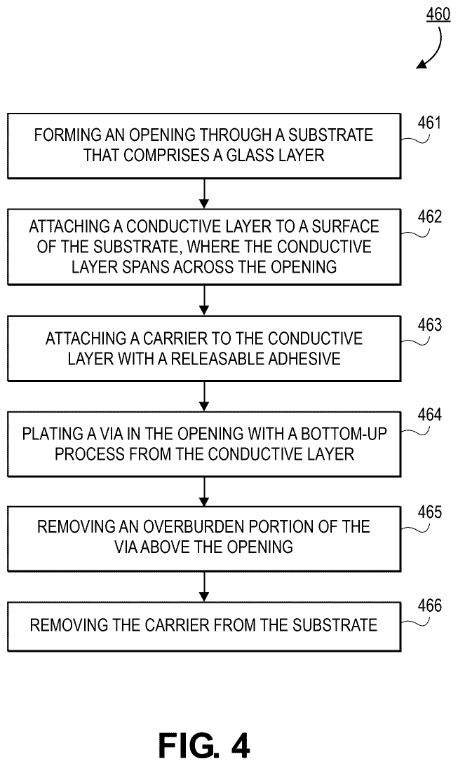

Referring now to FIG. 4, a flow diagram that depicts a process 460 for forming TGVs in a glass core with a bottom-up plating process is shown, in accordance with an embodiment. In an embodiment, the process 460 may be similar to any of the bottom-up plating processes described in greater detail. For example, the TGVs may have vias with a textured surface that reduces stress generation in the glass core due to CTE mismatch issues. The glass cores may be attached to a carrier with releasable adhesive during the bottom-up plating.

In an embodiment, the process 460 may begin with operation 461, which comprises forming an opening through a substrate that comprises a glass layer. In an embodiment, the substrate may be similar to any of the glass cores described in greater detail herein. In an embodiment, the opening may be considered a via opening. The opening may be formed with any suitable patterning process, such as a laser assisted etching process or the like.

In an embodiment, the process 460 may continue with operation 462, which comprises attaching a conductive layer to a surface of the substrate. In an embodiment, the conductive layer spans across the opening. The conductive layer may be a seed layer that is used to plate up the vias. The conductive layer may be applied onto the surface of the substrate with a lamination process, a slit coating process, an electroless process, or the like. In some embodiments, a portion of the conductive layer may deposit on a portion of a sidewall of the via opening adjacent to the surface that is covered by the conductive layer (e.g., similar to the embodiment shown in FIG. 1B).

In an embodiment, the process 460 may continue with operation 463, which comprises attaching a carrier to the conductive layer with a releasable adhesive. In an embodiment, the releasable adhesive may be an adhesive material that is able to be deactivated when a stimulus is applied. For example, the stimulus may include a thermal stimulus, a UV stimulus, a laser stimulus, or the like.

In an embodiment, the process 460 may continue with operation 464, which comprises plating a via in the opening with a bottom-up process from the conductive layer. For example, the conductive adhesive may span the opening, and the exposed portion of the conductive adhesive can be used as a seed layer to plate up the via. This allows for the via to be plated so that the opening is filled from bottom to top. Similar to other embodiments described herein, the plated via may have a textured surface that allows for the formation of submicron sized gaps between an edge of the via and the sidewall of the magnetic layer. Accordingly, the mechanical coupling is reduced, and stress induced by CTE mismatches between the via and the substrate are minimized. As such, reliability of the substrate is improved.

In an embodiment, the process may continue with operation 465, which comprises removing an overburden portion of the via above the opening. For example, a polishing process may be used to remove the overburden that is formed above a top surface of the substrate opposite from the carrier. For example, a CMP process may be used in some embodiments.

In an embodiment, the process 460 may continue with operation 466, which comprises removing the carrier from the substrate. In an embodiment, the carrier may be removed by applying the stimulus to the adhesive layer. The stimulus (e.g., a thermal stimulus, a UV stimulus, a laser stimulus, etc.) may deactivate the releasable adhesive, which allows for the substrate to be removed from the carrier. In an embodiment, residual portions of the conductive layer may be removed from the bottom surface of the carrier with an etching process or the like.

In an embodiment, the resulting substrate may then be integrated into a package substrate through typical buildup layer manufacturing processes. For example, a plurality of laminated layers are patterned to form electrical routing. The electrical routing in the buildup layers may electrically couple the via to a die coupled to the package substrate in some embodiments.

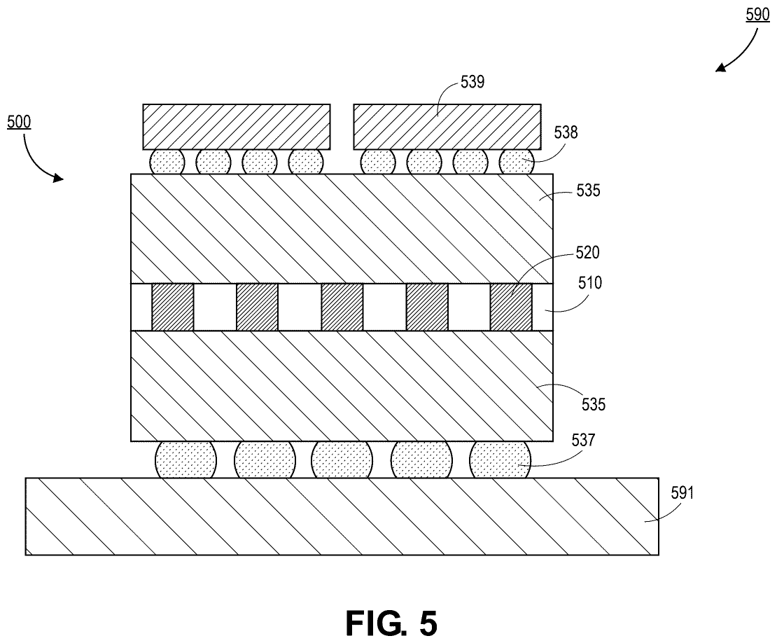

Referring now to FIG. 5, a cross-sectional illustration of an electronic system 590 is shown, in accordance with an embodiment. In an embodiment, the electronic system 590 may comprise a board 591, such as a printed circuit board (PCB), a motherboard, or the like. In an embodiment, the board 591 may be coupled to a package substrate 500 by SLIs 537. In an embodiment, the SLIs 537 may comprise solder balls, sockets, or the like.

In an embodiment, the package substrate 500 may be similar to any of the package substrates described in greater detail herein. In an embodiment, the package substrate 500 may comprise a glass core 510 with TGVs 520. The TGVs 520 may be formed with a bottom-up plating process such as any of those described in greater detail herein. In an embodiment, the TGVs 520 may have textured surfaces that allow for a reduction in an amount of stress that is induced in the glass core 510 due to weaker mechanical coupling compared to existing plating processes. The TGVs 520 may be similar to any of the TGVs described in greater detail herein. In an embodiment, the package substrate 500 may also comprise buildup layers 535 that are provided over and under the glass core 510.

In an embodiment, one or more dies 539 may be coupled to the buildup layer 535 by FLIs 538. The FLIs 538 may be any suitable FLI architecture, such as solder balls, copper bumps, hybrid bonding interfaces, or the like. In an embodiment, the one or more dies 539 may be any type of die (e.g., a processor die (e.g., a central processing unit (CPU), a graphics processing unit (GPU), an XPU), a memory die, a communications die, a power management die, and/or the like). In an embodiment, two or more dies 539 may be electrically coupled together by a bridge (not shown) that is embedded in the buildup layer 535 or provided over the buildup layer 535.

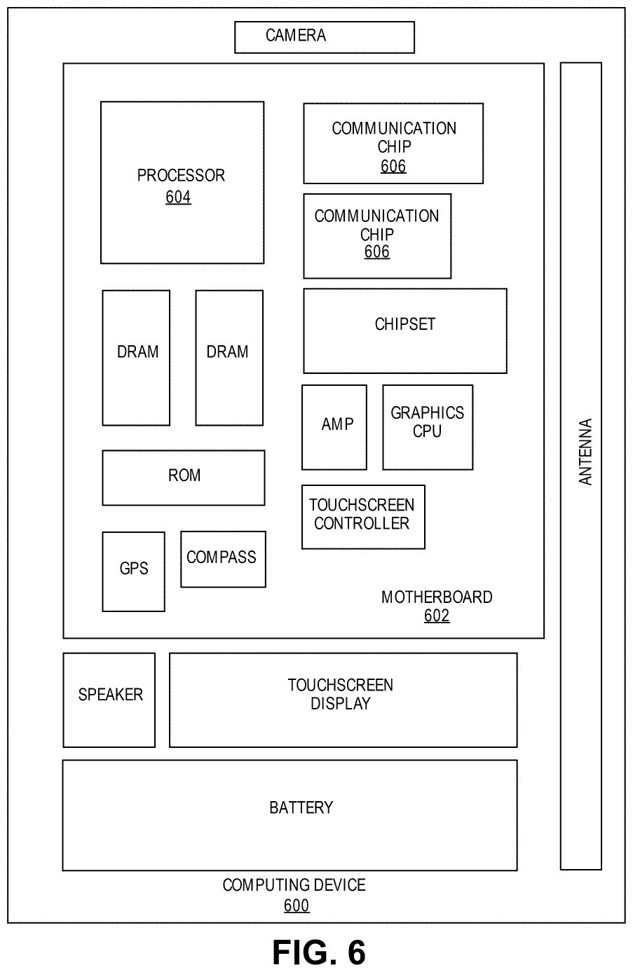

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a glass core that comprises TGVs that are formed with a bottom-up plating process, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a glass core that comprises TGVs that are formed with a bottom-up plating process, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate, wherein the substrate comprises a glass layer; an opening through a thickness of the substrate, wherein the opening has a first end at a first surface of the substrate and a second end at a second surface of the substrate; a layer on a sidewall of the opening, wherein the layer is adjacent to the first end of the opening and extends along the sidewall of the opening a length that is less than ten percent of the thickness of the substrate, and wherein the layer is electrically conductive; and a via in the opening, wherein the via directly contacts the sidewall of the opening at a first location, wherein a gap is provided between the via and the sidewall of the opening at a second location, and wherein the via is electrically conductive.
Example 2: the apparatus of Example 1, wherein the via directly contacts the layer.
Example 3: the apparatus of Example 1 or Example 2, wherein the length is less than 5 μm.
Example 4: the apparatus of Examples 1-3, wherein the layer comprises one or more of copper, titanium, or ruthenium.
Example 5: the apparatus of Examples 1-4, wherein a composition of the via is substantially uniform across a line from a first edge of the via to a second edge of the via that is parallel to a top surface and/or a bottom surface of the substrate.
Example 6: the apparatus of Example 5, wherein the composition comprises substantially copper.
Example 7: the apparatus of Examples 1-6, wherein an aspect ratio (height:width) of the opening is approximately 10:1 or greater.
Example 8: the apparatus of Examples 1-7, wherein the gap has a width that is up to one micron.
Example 9: the apparatus of Examples 1-8, wherein the substrate is a core of a package substrate.
Example 10: a method, comprising: forming an opening through a substrate that comprises a glass layer; attaching a conductive layer to a surface of the substrate, where the conductive layer spans across the opening; attaching a carrier to the conductive layer with a releasable adhesive; plating a via in the opening with a bottom-up process from the conductive layer; and removing the carrier from the substrate by applying a release stimulus to the releasable adhesive.
Example 11: the method of Example 10, wherein the releasable adhesive is a thermal release layer.
Example 12: the method of Example 10 or Example 11, wherein the releasable adhesive is an ultraviolet (UV) release layer.
Example 13: the method of Examples 10-12, wherein the releasable adhesive is laser release layer.
Example 14: the method of Examples 10-13, further comprising: forming a second opening through a second substrate that comprises a second glass layer; attaching a second conductive layer to a second surface of the second substrate, wherein the second conductive layer spans across the second opening; attaching the carrier to the second conductive layer with a second releasable adhesive, wherein the second conductive layer is attached to an opposite surface of the carrier from the conductive layer.
Example 15: the method of Examples 10-14, wherein the substrate is a panel level substrate.
Example 16: the method of Examples 10-15, wherein the carrier comprises glass.
Example 17: the method of Examples 10-16, wherein the via directly contacts a sidewall of the opening at a first location along the sidewall of the opening, and wherein the via is spaced away from the sidewall of the opening by a gap at a second location along the sidewall of the opening.
Example 18: an apparatus, comprising: a glass core; an opening through a thickness of the glass core, wherein the opening has a first end at a first surface of the glass core and a second end at a second surface of the glass core; a via in the opening, wherein the via has a textured surface that directly contacts a sidewall of the opening at a plurality of first locations and is spaced away from the sidewall by a plurality of gaps at a plurality of second locations, and wherein the via is electrically conductive; and a layer adjacent to the first end of the opening, wherein the layer extends into the opening to up to 5 μm.
Example 19: the apparatus of Example 18, further comprising: buildup layers over the first surface and the second surface of the glass core.
Example 20: the apparatus of Example 19, further comprising: a die coupled to the buildup layers on a first side of the apparatus; and a board coupled to the buildup layers on a second side of the apparatus.

What is claimed is:

1. An apparatus, comprising:
a substrate, wherein the substrate comprises a glass layer;
an opening through a thickness of the substrate, wherein the opening has a first end at a first surface of the substrate and a second end at a second surface of the substrate;
a layer on a sidewall of the opening, wherein the layer is adjacent to the first end of the opening and extends along the sidewall of the opening a length that is less than ten percent of the thickness of the substrate, and wherein the layer is electrically conductive; and
a via in the opening, wherein the via directly contacts the sidewall of the opening at a first location, wherein a gap is provided between the via and the sidewall of the opening at a second location, and wherein the via is electrically conductive.

2. The apparatus of claim 1, wherein the via directly contacts the layer.

3. The apparatus of claim 1, wherein the length is less than 5 μm.

4. The apparatus of claim 1, wherein the layer comprises one or more of copper, titanium, or ruthenium.

5. The apparatus of claim 1, wherein a composition of the via is substantially uniform across a line from a first edge of the via to a second edge of the via that is parallel to a top surface and/or a bottom surface of the substrate.

6. The apparatus of claim 5, wherein the composition comprises substantially copper.

7. The apparatus of claim 1, wherein an aspect ratio (height:width) of the opening is approximately 10:1 or greater.

8. The apparatus of claim 1, wherein the gap has a width that is up to one micron.

9. The apparatus of claim 1, wherein the substrate is a core of a package substrate.

10. A method, comprising:
forming an opening through a substrate that comprises a glass layer;
attaching a conductive layer to a surface of the substrate, where the conductive layer spans across the opening;
attaching a carrier to the conductive layer with a releasable adhesive;
plating a via in the opening with a bottom-up process from the conductive layer; and
removing the carrier from the substrate by applying a release stimulus to the releasable adhesive.

11. The method of claim 10, wherein the releasable adhesive is a thermal release layer.

12. The method of claim 10, wherein the releasable adhesive is an ultraviolet (UV) release layer.

13. The method of claim 10, wherein the releasable adhesive is laser release layer.

14. The method of claim 10, further comprising:
forming a second opening through a second substrate that comprises a second glass layer;
attaching a second conductive layer to a second surface of the second substrate, wherein the second conductive layer spans across the second opening;
attaching the carrier to the second conductive layer with a second releasable adhesive, wherein the second conductive layer is attached to an opposite surface of the carrier from the conductive layer.

15. The method of claim 10, wherein the substrate is a panel level substrate.

16. The method of claim 10, wherein the carrier comprises glass.

17. The method of claim 10, wherein the via directly contacts a sidewall of the opening at a first location along the sidewall of the opening, and wherein the via is spaced away from the sidewall of the opening by a gap at a second location along the sidewall of the opening.

18. An apparatus, comprising:
a glass core;
an opening through a thickness of the glass core, wherein the opening has a first end at a first surface of the glass core and a second end at a second surface of the glass core;
a via in the opening, wherein the via has a textured surface that directly contacts a sidewall of the opening at a plurality of first locations and is spaced away from the sidewall by a plurality of gaps at a plurality of second locations, and wherein the via is electrically conductive; and
a layer adjacent to the first end of the opening, wherein the layer extends into the opening to up to 5 μm.

19. The apparatus of claim 18, further comprising:
buildup layers over the first surface and the second surface of the glass core.

20. The apparatus of claim 19, further comprising:
a die coupled to the buildup layers on a first side of the apparatus; and
a board coupled to the buildup layers on a second side of the apparatus.
